(19) United States
(12) Patent Application Publication
(10) Pub. No.: US 2025/0224426 A1
(43) Pub. Date: Jul. 10, 2025

(54) CURRENT SENSOR ASSEMBLY

(71) Applicant: Vertiv Corporation, Westerville, OH (US)

(72) Inventors: Raviraj Prakash Sumbe, Kolhapur (IN); Rajan Suresh Borole, Thane (IN)

(21) Appl. No.: 19/003,334

(22) Filed: Dec. 27, 2024

(30) Foreign Application Priority Data
Dec. 29, 2023 (IN) 202321089862

(51) Int. Cl. G01R 15/20; G01R 19/00

(52) U.S. Cl. CPC G01R 15/202; G01R 19/0092

(57) ABSTRACT

A current sensor assembly includes at least a portion of a printed circuit board; at least one sensor disposed on the portion of the printed circuit board, the at least one sensor being configured to measure current flowing through the portion of the printed circuit board; and a processing unit configured to: receive one or more current measurements from the at least one sensor; and determine an actual current value associated with the current flowing through the portion of the printed circuit board by scaling the one or more current measurements.

### CROSS REFERENCE TO RELATED APPLICATIONS

This U.S. Non-Provisional Patent Application claims the benefit of Indian Provisional Patent Application Ser. No. 20/232,1089862 titled “A Current Sensor Assembly” filed Dec. 29, 2023, the entire disclosure of which is hereby incorporated by reference.

### FIELD

The present disclosure relates to current sensors.

### BACKGROUND

The background information herein below relates to the present disclosure but is not necessarily prior art.

Typically, power conversion systems use dedicated current sensors for measuring the current flowing through the systems. These dedicated sensors have a defined measuring capacity, which means that the sensors are incapable of measuring current beyond their capacity. For example, if 50 A current flowing through the system is to be measured, then a current sensor of 50 A capacity must be used. Similarly, 100 A capacity current sensor is needed for measuring 100 A current.

However, as the current capacity of the sensor increases, the cost of the current sensor also increases, subsequently increasing the production cost of the system. Further, current sensors of higher capacity have larger dimensions, and therefore tend to occupy more space on elements of the power system such as its PCB.

### SUMMARY

An aspect of the disclosed embodiments includes a current sensor assembly. The current sensor assembly includes at least a portion of a printed circuit board; at least one sensor disposed on the portion of the printed circuit board, the at least one sensor being configured to measure current flowing through the portion of the printed circuit board; and a processing unit configured to: receive one or more current measurements from the at least one sensor; and determine an actual current value associated with the current flowing through the portion of the printed circuit board by scaling the one or more current measurements.

### BRIEF DESCRIPTION OF THE ACCOMPANYING DRAWING

A current sensor assembly of present disclosure will now be described with the help of the accompanying drawing, in which:

FIG. 1 illustrates an isometric view of the assembly, in accordance with a first embodiment of the present disclosure; and

FIGS. 2 and 3 illustrate isometric views of the assembly, in accordance with a second embodiment of the present disclosure.

### DETAILED DESCRIPTION

Embodiments, of the present disclosure, will now be described with reference to the accompanying drawing.

Embodiments are provided so as to thoroughly and fully convey the scope of the present disclosure to a person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, elements, modules, units, and/or components, but do not forbid the presence or addition of one or more other features, elements, components, and/or groups thereof.

In some embodiments, the systems and methods described herein may be configured to ameliorate one or more problems of the prior art or to at least provide a useful alternative. The systems and methods described herein may be configured to provide a current sensor assembly. The systems and methods described herein may be configured to provide a current sensor assembly which can be used for measuring current beyond its current sensor capacity.

The systems and methods described herein may be configured to provide a current sensor assembly which may reduce build of material or production costs. The systems and methods described herein may be configured to provide a current sensor assembly which occupies a relatively smaller surface area on a power system element.

In some embodiments, the systems and methods described herein may be configured to provide a current sensor assembly may be used for measuring current beyond its current capacity.

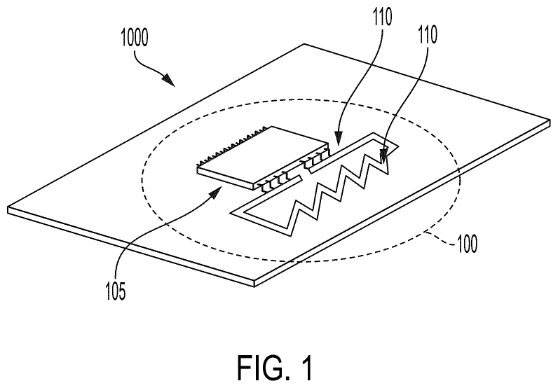

A current sensor assembly (100, 200), of the present disclosure will now be destined in detail with reference to FIG. 1 through FIG. 3. It should be understood that, the description of FIG. 1 through FIG. 3 does not limit the scope and ambit of the present disclosure.

The current sensor assembly (100, 200) is configured to be employed in a power system to measure the current flowing therethrough.

In some embodiments, the current sensor assembly (100, 200) (hereinafter referred to as ‘the assembly (100, 200)’) includes a current sensor (105, 205) configured to be provided on an element of the power system, such as a printed circuit board (PCB) (1000).

FIG. 1 illustrates an isometric view of the assembly (100), which may include a PCB (1000) having the sensor (105) and a conductive track (110) configured thereon.

In some embodiments, the current sensor (105) is a Hall-effect sensor. In some embodiments, the current sensor (105) can have any current capacity, and is not restricted by the highest value of current flowing through the PCB (1000). In some embodiments, the current capacity of the sensor (105) is lesser than the estimated current that would flow through the PCB (1000).

In some embodiments, the impedance of the conductive track (110) is matched with the impedance of the sensor (105). In some embodiments, it is preferred that the parameter of impedance of the conductive track (110) is matched with that of the sensor (105) as impedance includes both resistance and reactance. It is required that the impedance of the track (110) is simulated at the time of PCB (1000) layout.

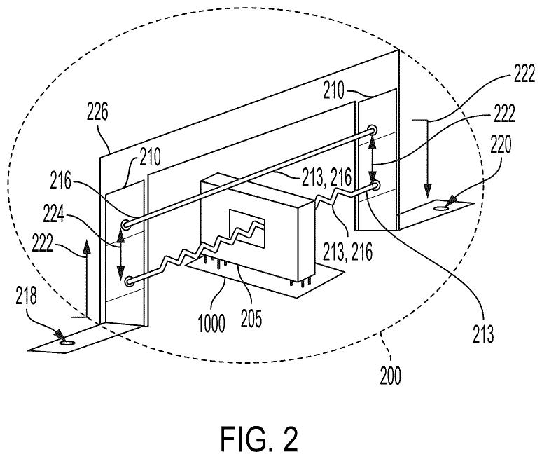

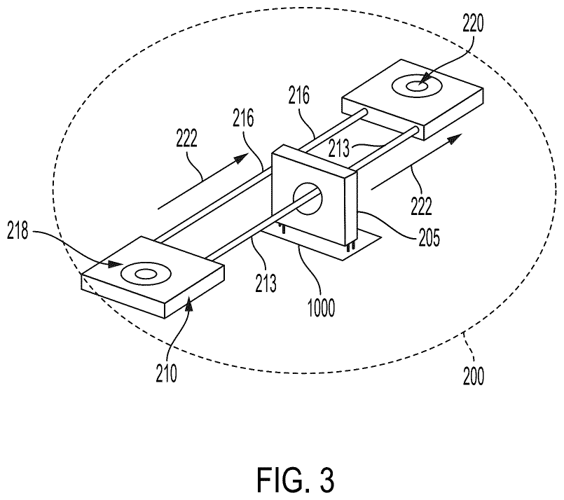

FIG. 2 and FIG. 3 illustrates an isometric view of a second embodiment of the present disclosure, wherein the assembly (200) includes a PCB (1000) having a sensor (205) and a busbar (210) provided thereon. In some embodiments, the PCB (1000) may include any suitable number of busbars (210), including but not limited to at least one busbar (210) or other suitable number of busbars (210)

In some embodiments, the busbar (210) is configured on the PCB (1000), parallel to the sensor (105, 205). The busbar (210) is configured to receive and conduct electricity therethrough. Further, referring to FIG. 2 for the busbar (210), the busbar conductors (213, 216) used should be equal in impedance. This can be achieved by increasing length of busbar conductor (213) to compensate the distance between conductors (224). Also, it is required that the conductor placements in the assembly (100, 200) are properly placed for better accuracy.

In some embodiments, FIG. 2 illustrates one embodiment of the provision of busbar (210) for sensing the current. The busbar conductor placement is positioned closer to the current incoming point and the current outgoing point.

In some embodiments, FIG. 3 illustrates another embodiment of the provision of busbar (210) for sensing the current. The busbar conductors (213, 216) are placed at equidistantly from the current incoming point (218) and the current outgoing point (220). In some embodiments, for the busbar (210), the busbar conductors (213, 216) used have equal length, width, diameter (if it is round shaped) and material (which could be copper or aluminum). The second embodiment provides a comparatively accurate reading of the current.

In some embodiments, the assembly (100, 200) is used where the typical value of the current flowing through the system is already identified in its specifications. The sensor (105, 205) is configured to be measure the value of the current, and is coupled to a processing unit, to detect whether there are current fluctuations in the system. The conductive track (110) parallel to the current sensor (105) or the busbar conductor (216) parallel to the busbar conductor (213) is configured to receive the equal amount of current flowing through the current sensor (105, 205),

So, the total amount of current flowing through the system is beyond the capacity rating of the sensor (105, 205).

In a working configuration of the assembly (100, 200), the sensor (105, 205) is connected to a processing unit, to transmit the measured current value to the processing unit. The processing unit is configured to scale the received measured value to form the actual value of current.

In accordance with some embodiments, current of 100 A is made to flow through a PCB (1000). A sensor (105, 205) of 50 A is mounted on the PCB (1000). In this case, the sensor (105, 205) is unable to measure current beyond its rated capacity of 50 A. Therefore, a conductive track is configured parallel to the sensor (105, 205) to receive the excess 50 A of current therein. The value of 50 A measured by the sensor (105, 205) is received by the processing unit which scales it up by a factor of 2 (the factor of scaling up is calculated by the details of the specification of the PCB (1000)) to calculate the actual current value which in this case is 100 A.

In accordance with some embodiments, current of 150 A is made to flow through a PCB (1000). A sensor (105, 205) of 50 A is mounted on the PCB (1000). In this case, the sensor (105, 205) is unable to measure current beyond its rated capacity of 100 A. Therefore, a pair of conductive tracks is configured parallel to the sensor (105, 205) to receive the excess 100 A of current therein. The value of 50 A measured by the sensor (105, 205) is received by the processing unit which scales it up by a factor of 3 to calculate the actual current value which in this case is 100 A.

The number of tracks (n) thus, is dependent on the scaling factor (n+1).

The sensor assembly (100, 200) of the present disclosure, thus utilizes a lower rated capacity of sensor (105, 205) to measure higher current values, thereby lowering the BOM cost. Further, the lower rated capacity sensor (105, 205) occupies relatively lesser surface area of the PCB (1000).

In some embodiments, a current sensor assembly includes at least a portion of a printed circuit board; at least one sensor disposed on the portion of the printed circuit board, the at least one sensor being configured to measure current flowing through the portion of the printed circuit board; and a processing unit configured to: receive one or more current measurements from the at least one sensor; and determine an actual current value associated with the current flowing through the portion of the printed circuit board by scaling the one or more current measurements.

In some embodiments, the printed circuit board includes one or more conductive tracks. In some embodiments, the one or more conductive tracks are disposed on the printed circuit board in parallel to the at least one sensor. In some embodiments, the processing unit is further configured to scale the one or more current measurements based on a number of conductive tracks of the one or more conductive tracks. In some embodiments, the processing unit is further configured to scale the one or more current measurements by multiplying the one or more current measurements by the number of conductive tracks of the one or more conductive tracks. In some embodiments, an impedance of the one or more conductive tracks is matched with an impedance of the at least one sensor. In some embodiments, the one or more conductive tracks are configured to receive an amount of currently equal to an amount of current flowing through the at least one sensor. In some embodiments, the at least one sensor includes a Hall-effect sensor. In some embodiments, the at least one sensor has a current capacity that is less than an estimated current of the printed circuit board. In some embodiments, the printed circuit board includes at least one busbar. In some embodiments, the at least one busbar is disposed parallel to the at least one sensor. In some embodiments, the at least one busbar includes at least two conductors. In some embodiments, the at least two conductors have equal impedance. In some embodiments, the at least two conductors are of equal length. In some embodiments, the at least two conductors are of equal width. In some embodiments, the at least two conductors are of equal diameter. In some embodiments, the at least one busrbar is disposed on the printed circuit board equidistant between a current incoming portion and a current outgoing portion. In some embodiments, the at least one busbar is configured to receive an amount of currently equal to an amount of current flowing through the at least one sensor. In some embodiments, the processing unit is configured to detect fluctuations in current flowing through the printed circuit board. In some embodiments, the printed circuit board is associated with a power system.

The foregoing description of the embodiments has been provided for purposes of illustration and not intended to limit the scope of the present disclosure. Individual components of a particular embodiment are generally not limited to that particular embodiment but are interchangeable. Such variations are not to be regarded as a departure from the present disclosure, and all such modifications are considered to be within the scope of the present disclosure.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully reveals the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprises”, or variations such as “comprises” or “comprising”, will be understood to imply the inclusion of a stated element, or group of elements, but not the exclusion of any other element, or group of elements.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

What is claimed is:

1. A current sensor assembly, comprising:
at least a portion of a printed circuit board;
at least one sensor disposed on the portion of the printed circuit board, the at least one sensor being configured to measure current flowing through the portion of the printed circuit board; and
a processing unit configured to:
receive one or more current measurements from the at least one sensor; and
determine an actual current value associated with the current flowing through the portion of the printed circuit board by scaling the one or more current measurements.

2. The current sensor assembly of claim 1, wherein the printed circuit board includes one or more conductive tracks.

3. The current sensor assembly of claim 2, wherein the one or more conductive tracks are disposed on the printed circuit board in parallel to the at least one sensor.

4. The current sensor assembly of claim 2, wherein the processing unit is further configured to scale the one or more current measurements based on a number of conductive tracks of the one or more conductive tracks.

5. The current sensor assembly of claim 4, wherein the processing unit is further configured to scale the one or more current measurements by multiplying the one or more current measurements by the number of conductive tracks of the one or more conductive tracks.

6. The current sensor assembly of claim 2, wherein an impedance of the one or more conductive tracks is matched with an impedance of the at least one sensor.

7. The current sensor assembly of claim 2, wherein the one or more conductive tracks are configured to receive an amount of currently equal to an amount of current flowing through the at least one sensor.

8. The current sensor assembly of claim 1, wherein the at least one sensor includes a Hall-effect sensor.

9. The current sensor assembly of claim 1, wherein the at least one sensor has a current capacity that is less than an estimated current of the printed circuit board.

10. The current sensor assembly of claim 1, wherein the printed circuit board includes at least one busbar.

11. The current sensor assembly of claim 10, wherein the at least one busbar is disposed parallel to the at least one sensor.

12. The current sensor assembly of claim 10, wherein the at least one busbar includes at least two conductors.

13. The current sensor assembly of claim 12, wherein the at least two conductors have equal impedance.

14. The current sensor assembly of claim 12, wherein the at least two conductors are of equal length.

15. The current sensor assembly of claim 12, wherein the at least two conductors are of equal width.

16. The current sensor assembly of claim 12, wherein the at least two conductors are of equal diameter.

17. The current sensor assembly of claim 10, wherein the at least one busrbar is disposed on the printed circuit board equidistant between a current incoming portion and a current outgoing portion.

18. The current sensor assembly of claim 10, wherein the at least one busbar is configured to receive an amount of currently equal to an amount of current flowing through the at least one sensor.

19. The current sensor assembly of claim 1, wherein the processing unit is configured to detect fluctuations in current flowing through the printed circuit board.

20. The current sensor assembly of claim 1, wherein the printed circuit board is associated with a power system.
